(19) United States
(12) Patent Application Publication
(10) Pub. No.: US 2013/0023111 A1
(43) Pub. Date: Jan. 24, 2013

(54) LOW TEMPERATURE METHODS AND APPARATUS FOR MICROWAVE CRYSTAL REGROWTH

(71) Applicant: Robert J. Purtell, West Jordan, UT (US)

(72) Inventor: Robert J. Purtell, West Jordan, UT (US)

(21) Appl. No.: 13/535,082

(22) Filed: Jun. 27, 2012

Related U.S. Application Data
(60) Provisional application No. 61/502,430, filed on Jun. 29, 2011.

(51) Int. Cl. H01L 21/20

(52) U.S. Cl. 438/486; 438/488; 438/478; 438/607; 257/E21.09

(57) ABSTRACT

Semiconductor devices and methods for making such devices are described. The semiconductor devices contain an epitaxial layer made by providing a semiconductor substrate containing an upper surface with a single-crystal structure; forming a layer on the upper surface of the substrate, wherein the layer comprises substantially the same material as the semiconductor substrate and comprises an amorphous or polycrystalline structure; and heating the layer using low temperature microwaves to change the amorphous structure to a single-crystal structure. The epitaxial layer can also be made by providing the semiconductor substrate with an upper surface of a single-crystal material and then forming an epitaxial layer on the substrate upper surface using microwaves at a wafer temperature less than about 550° C. In-situ or implanted dopants in the epitaxial layer can be activated using the same, or separate, low temperature microwave processing. Other embodiments are described.

### CROSS-REFERENCE TO RELATED APPLICATION

This application claims priority of U.S. Provisional Application Ser. No. 61/502,430 filed Jun. 29, 2011, the entire disclosure of which is incorporated herein by reference.

### FIELD

This application relates generally to semiconductor devices and methods for making such devices. More specifically, this application describes semiconductor devices containing epitaxial layers formed using low temperature microwave processing and apparatus for making such devices.

### BACKGROUND

Semiconductor devices containing integrated circuits (ICs) or discrete devices are used in a wide variety of electronic apparatus. The IC devices (or chips or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning. Silicon wafers are typically used as the substrate and photolithography is used to mark different areas of the substrate to be doped or to deposit and define polysilicon, insulators, or metal layers.

One type of semiconductor device, a metal oxide silicon field effect transistor (MOSFET) device, can be widely used in numerous electronic apparatus, including automotive electronics, disk drives and power supplies. Some MOSFET devices can be formed in a trench that has been created in the substrate. One feature making the trench configuration attractive is that the current flows vertically through the channel of the MOSFET. This permits a higher cell and/or current channel densities than other MOSFETs where the current flows horizontally through the channel and then vertically through the drain. The trench MOSFET devices contain a gate structure formed in the trench where the gate structure contains a gate insulating layer on the sidewall and bottom of the trench (i.e., adjacent the substrate material) with a conductive layer that has been formed on the gate insulating layer.

### SUMMARY

This application describes semiconductor devices containing epitaxial layers formed using microwave processing at low temperatures and apparatus for making such devices. The semiconductor devices contain an epitaxial layer made by providing a semiconductor substrate containing an upper surface with a single-crystal structure; forming a layer on the upper surface of the substrate, wherein the layer comprises substantially the same material as the semiconductor substrate and comprises an amorphous or polycrystalline structure; and heating the layer using microwaves at low processing temperatures to change the amorphous structure to a single-crystal structure. The epitaxial layer can also be made by providing the semiconductor substrate with an upper surface of a single-crystal material and then forming an epitaxial layer on the substrate upper surface using microwaves at a wafer temperature less than about 550° C. In-situ or implanted dopants in the epitaxial layer can be activated using the same, or separate, low temperature microwave processing. A batch reactor can be used at low temperatures with microwave processing which deposits an epitaxial layer on multiple wafers at the same time with the desired uniformity, thereby greatly improving the yield and lowering the manufacturing costs.

### BRIEF DESCRIPTION OF THE DRAWINGS

The following description can be better understood in light of the Figures, in which:

FIG. 1 shows some embodiments of methods for making a semiconductor structure containing a substrate and an epitaxial (or “epi”) layer;

FIG. 2 depicts some embodiments of methods for making a semiconductor structure containing an amorphous (or polycrystalline) Si layer heated with low-temperature microwaves;

FIG. 3 depicts some embodiments of methods for making a semiconductor structure containing a trench; and

FIGS. 4-5 show some embodiments of methods for making a semiconductor structure by using a batch reactor.

The Figures illustrate specific aspects of the semiconductor devices containing epitaxial layers formed using low temperature microwave processing and apparatus for making such devices. Together with the following description, the Figures demonstrate and explain the principles of the methods and structures produced through these methods. In the drawings, the thickness of layers and regions are exaggerated for clarity. The same reference numerals in different drawings represent the same element, and thus their descriptions will not be repeated. As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while the description refers to U-MOS (U-shaped MOSFET) semiconductor devices, it could be modified for any other type of semiconductor devices which may or may not contain gate structures formed in a trench, such as LDMOS or CMOS devices.

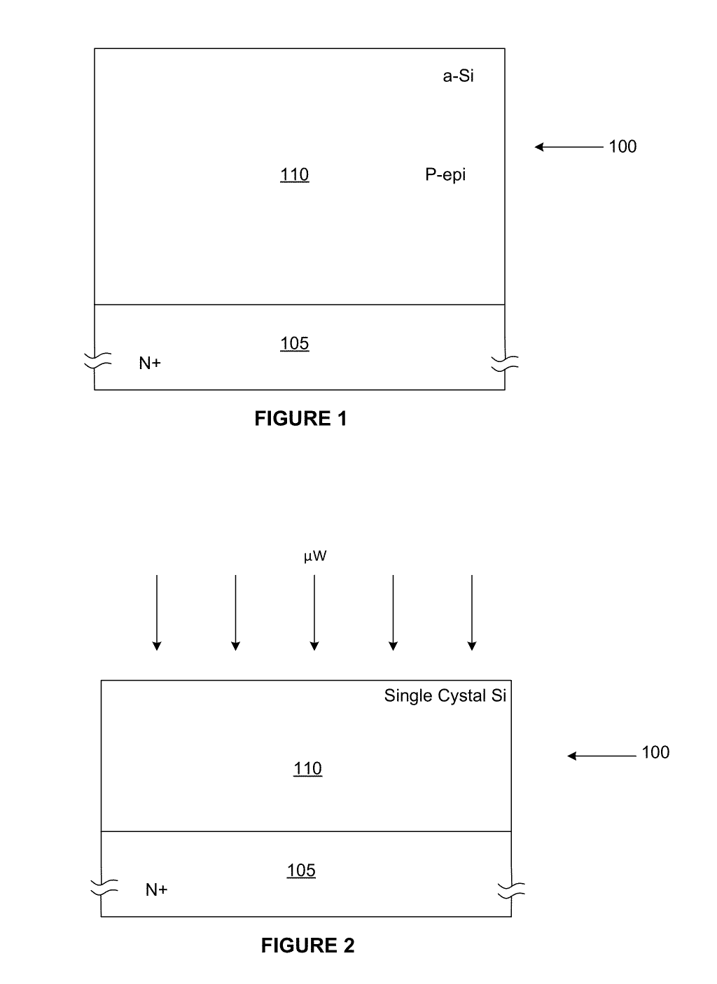

Some embodiments of the semiconductor devices containing epitaxial layers formed using low temperature microwave processing and apparatus for making such devices are illustrated in FIGS. 1-5 and described herein. In these embodiments, the methods can begin as depicted in FIG. 1 when a semiconductor substrate 105 is first provided as part of the semiconductor structure 100. Any semiconductor substrate known in the art can be used as the substrate 105. Examples of some substrates include single-crystal silicon wafers, epitaxial Si layers, and/or bonded wafers such as used in silicon-on-insulator (SOI) technologies. Also, any other semiconducting material typically used for electronic devices can be used as the material for the substrate 105 under the right conditions, including Ge, SiGe, GaN, C, and/or any pure or compound semiconductors, such as III-V or II-VIs and their variants. Any or all of these substrates may remain undoped or be doped with any number of p-type or n-type dopant or combination of dopants. In some configurations, the substrate 105 comprises a single-crystal Si wafer which is heavily doped with any type or number of n-type dopants to the desired concentration. In other configurations, the substrate 105 contains a single-crystal epitaxial layer on part or its entire upper surface.

The semiconductor structure 100 can optionally contain one or more epitaxial (or “epi”) layers located on a portion of the upper surface of the substrate 105. In FIG. 1, the individual epitaxial layer (or multiple epitaxial layers) are depicted as epitaxial layer 110. In some configurations, the epitaxial layer 110 covers substantially all of the upper surface of substrate 105. Where Si is used as the material for the substrate 105, the epitaxial layer 110 comprises Si. The epitaxial layer(s) 110 can be provided using any process in the art, including any epitaxial deposition process. In some instances, the epitaxial layer(s) can be lightly doped with any type of number of p-type dopants, as shown in FIG. 1.

Conventionally, some Si epitaxial layers have been manufactured by heating the Si substrate 105 in a silicon-containing gas mixture at high temperatures in a single-wafer epitaxial reactor. The gas mixture typically includes a gas containing silicon, such as silane, dichlorosilane, trichlorosilane, or combinations thereof. This gas mixture also contains a carrier gas, such as H₂ or N₂. This gas mixture can also contain a dopant gas with a gas (or gases) containing the dopant materials that will be incorporated into the epitaxial layer as it is deposited. The dopant gas can contain PH₃ (for P dopants), AsH₃ (for As dopants), H₂, or combinations thereof. Unfortunately, these dopant gases can be very toxic and pyrophoric, so special processing conditions are used. These processing conditions include using equipment that will maintain a vacuum in the deposition chamber, i.e., vacuum pumps, shrouding delivery lines operating under vacuum conditions, equipment that monitors for leaks, and specialized handling equipment. These special processing conditions and equipment raise the costs of the epitaxial deposition process.

As well, some of the conventional epitaxial deposition processes are often performed at high temperatures above 900° C. These higher temperatures can raise the costs of the epitaxial deposition process. As well, these higher temperatures require the use of the carrier gases described above, complicating the process and raising the cost. These carrier gases are used because the silicon material in the Si-containing gases can react with other gases in the gas mixture at such temperatures, reducing the amount of silicon material available to be deposited.

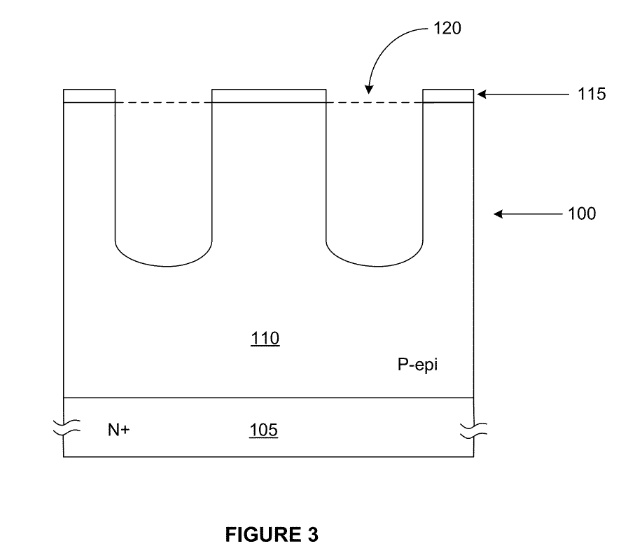

Because of these processing conditions for conventional epitaxial deposition, the epitaxial layer(s) 110 can be provided by using low temperature microwave processes in some embodiments. For example, in the embodiments illustrated in FIG. 2, the epitaxial layer 110 can be deposited by heating a Si-containing gas mixture using microwaves at low temperatures. In these embodiments, the Si-containing gas mixture can contain the same or different gases than those gases used in conventional processes, as described herein. In other embodiments, though, the Si-containing gas mixture can contain any Si-containing gas, such as silane, dichlorosilane, trichlorosilane, silicon tetrachloride, silicon tetrafluoride, trimethylsilane, or combinations thereof. This gas mixture can also contain a carrier gas, such as N₂, H₂, other inert gases, or combinations thereof. The use of N₂ and H₂ can provide significant safety advantages, especially at temperatures below 600° C. when N₂ can be used in place of H₂. In some configurations, the gas mixture with a silicon-containing gas can also contain a dopant gas (or gases) containing the dopants that can be incorporated into the epitaxial layer. The dopant gas mixture can contain PH₃ (for P dopants), AsH₃ (for As dopants), H₂, or combinations thereof.

The Si-containing gas mixture can be deposited as an epitaxial layer using microwaves while keeping the substrate at low temperatures. In some embodiments, these low temperatures can be less than about 550° C. In other embodiments, these low temperatures can range from about 200 to about 550° C. In yet other embodiments, the temperatures can range from about 400 to about 550° C. In still other embodiments, these low temperatures can be any suitable combination or sub-range of these temperatures.

The Si epitaxial layer can be deposited with any non-single crystal structure for the layers. Thus, in some embodiments, the Si epitaxial layer can be deposited so that part or substantially the entire layer comprises an amorphous structure. And in other embodiments, and under the right conditions, the Si epitaxial layer can be deposited so that part or substantially all of the layer comprises a polycrystalline structure.

The microwave heating process can use any frequency or wavelength of microwaves that are allowed for industrial applications by government regulations. In some embodiments, the frequency and wavelength of the microwaves can be any of those allowed by international regulations for industrial applications. In other embodiments, the frequency of the microwaves can range from about 2.45 GHz to about 5.8 GHz and have a wavelength ranging from about 52 mm to about 123 mm.

The microwave heating process can be performed for any time sufficient to form the epitaxial layer 110. In some embodiments, the time can range up to about 120 minutes, which is much shorter than the 5 to 6 hours that are often required in some conventional furnace processes used when forming epitaxial layers. In other embodiments, this time can range from about 1 minute to about 120 minutes. In yet other embodiments, the time can range from about 2 minutes to about 60 minutes. In still other embodiments, the time can range from about 2 minutes to about 15 minutes. In even other embodiments, the time can be any suitable combination or sub-range of these amounts.

In certain instances, a combination of rapid thermal processing (RTP) and microwave (MW) heating at low temperatures can be used to form the epitaxial layer 110. In these embodiments, the RTP is first used to deposit an amorphous silicon (a-Si) layer on at least a portion of the upper surface of the substrate 105. The low-temperature MW heating processes are described herein can then be used in the MW batch reactor 300 shown in FIG. 5, to re-grow that a-Si layer, but with a single crystal structure. In these embodiments, the RTP can be performed from about 900° C. to about 1100° C. for about 2 to about 15 minutes. The MW low temperature heating process can then be performed as an annealing process under the conditions described herein to regrow the a-Si (or polycrystalline) layer with the single crystal structure. In other embodiments, this MW annealing process can be performed using the same conditions as the in-situ MW recrystallization process described herein. For example, the deposited Si layer can comprise polycrystalline Si that could be converted to single-crystal Si by attaching the poly-Si to a desired crystal face of the Si-containing substrate [i.e., (111), (100), or (110) or (311)]. When the deposited layer is recrystallized, the underlying crystal plane propagates through the material as it recrystallizes.

The epitaxial layer 110 can also be doped with any desired (and number) of n-type or p-type dopant. In some embodiments, the epitaxial layer 110 can be doped with P and/or B dopants. In these embodiments, the concentration of the P and/or B dopants in the epitaxial layer 110 can range from about 2×10¹⁵ atoms/cm³ to about 1×10²⁰ atoms/cm³. In other embodiments, the concentration of the P and/or B dopants can range from about 1×10¹⁵ atoms/cm³ to about 2.5×10²⁰ atoms/cm³. In still other embodiments, the concentration can be any suitable combination or sub-range of these amounts.

The epitaxial layer 110 can be doped with these dopants using any process known in the art that will give that layer the desired dopant concentrations. In some embodiments, the P and/or B dopants can be added to the Si-containing gas mixture using a P and/or B-containing dopant gas(es), thereby doping the epitaxial layer 110 using an in situ process while the epitaxial layer is deposited. The P- and/or B-containing gas(es) that can be used include diborane, PH₃, BCL₃, or combinations thereof. In other embodiments, the desired dopant(s) can be provide in the epitaxial layer 10 using any implant and drive-in process.

Once located in the epitaxial layer 110, the dopants can then be activated by heating the doped layer with microwaves at low temperatures, if desired. This low temperature MW activation process functions not only to activate the dopants, but also to recrystallize the deposited grains and substantially orient them with respect to the substrate, if needed. In some embodiments, these low temperatures for the MW activation process can be less than about 800° C. In other embodiments, these low temperatures for the MW activation process can range from about 200 to about 800° C. In yet other embodiments, the temperatures for the MW activation process can range from about 200 to about 550° C. In still other embodiments, these low temperatures can be any suitable combination or sub-range of these temperatures. In even other embodiments, the dopants can be activated with microwaves at low temperatures using an in-situ process instead off—or in addition to—the post deposition MW annealing process. AS well, the MW activation process for activating the dopants can be the same or different than the MW heating process for recrystallizing the grains.

The microwave activation process can use any frequency or wavelength of microwaves that are allowed for industrial applications by government regulations. In some embodiments, the frequency and wavelength of the microwaves can be any of those allowed by international regulations for industrial applications. In other embodiments, the frequency of the microwaves can range from about 2.45 GHz to about 5.8 GHz and have a wavelength ranging from about 52 mm to about 123 mm.

The microwave activation process can be performed for any time sufficient to form the epitaxial layer 110. In some embodiments, the time can range up to about 120 minutes, which is much shorter than the 5 to 6 hours that are often required in some conventional furnace processes used when forming epitaxial layers. In other embodiments, this time can range from about 1 minute to about 120 minutes. In yet other embodiments, the time can range from about 2 minutes to about 60 minutes. In still other embodiments, the time can range from about 2 minutes to about 15 minutes. In even other embodiments, the time can be any suitable combination or sub-range of these amounts.

In some embodiments, a combination of rapid thermal processing (RTP) and a MW annealing process can be used to activate these dopants. In these embodiments, the RTP can be performed from about 900° C. to about 1100° C. for about 2 to about 15 minutes and the MW activation process can be performed from about 200° C. to about 550° C. for about 2 to about 30 minutes.

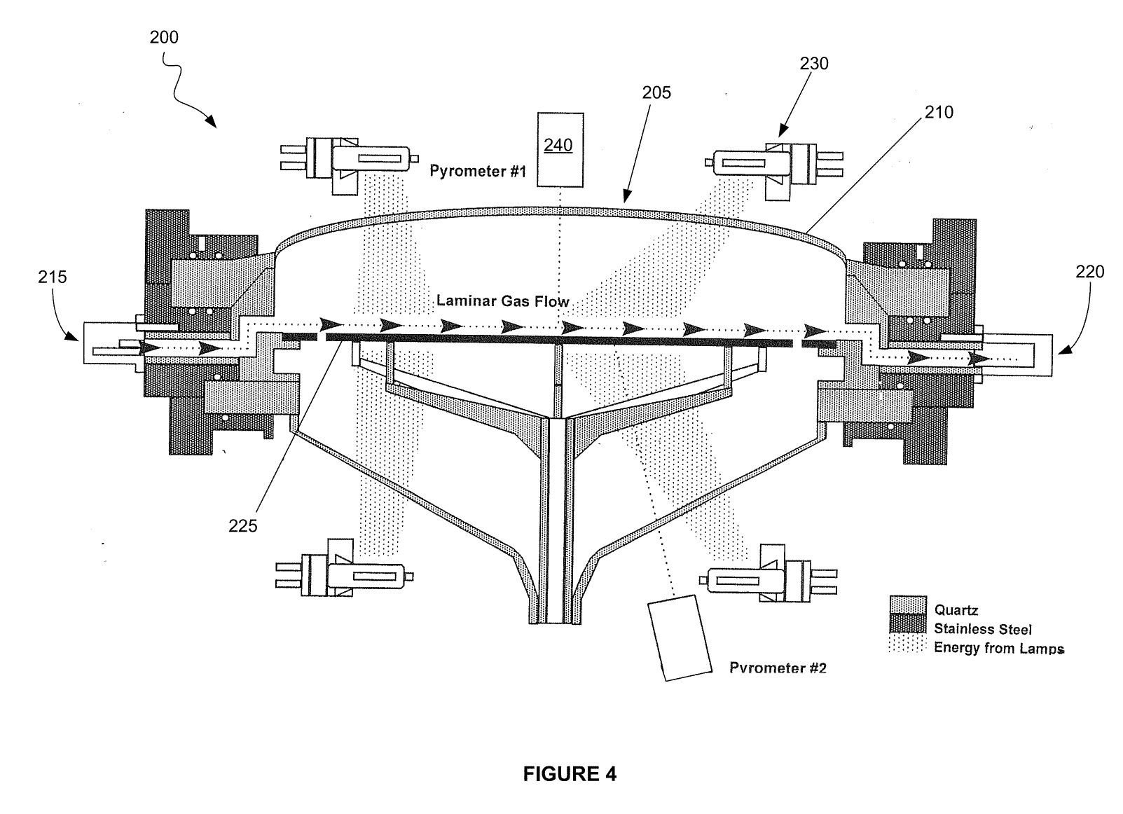

The remaining of the semiconductor device can then be manufactured as known in the art. In some embodiments, as shown in FIG. 3, a trench 120 can be formed in the epitaxial layer 110 (and optionally the substrate 105). The bottom of the trench 120 can reach any depth in the epitaxial layer 110 or the substrate 105. The trench 120 can be formed by any known process, including using a mask 115 formed on the upper surface of the epitaxial layer 110. In some embodiments, the epitaxial layer 110 can be etched using any known etchant until the trench 120 has reached the desired depth and width in the epitaxial layer 110. In these embodiments, a trench MOSFET structure can then be completed using any process known in the art.

As noted above, some conventional epitaxial deposition processes are limited in terms of the processing parameters at which they operate. But these processes also can be limited in the apparatus that can be used during the deposition process. Some conventional epitaxial deposition processes are performed in reactor chambers that deposit the epitaxial layer on only one wafer at a time in order to provide the needed uniformity and resistivity control. Yet other epitaxial reactors have a barrel or pancake design (containing a rotating platen) that allow a higher yield because they can deposit the epitaxial layer on multiple wafers at the same time. But these other reactors are not able to provide the desired uniformity and resistivity control.

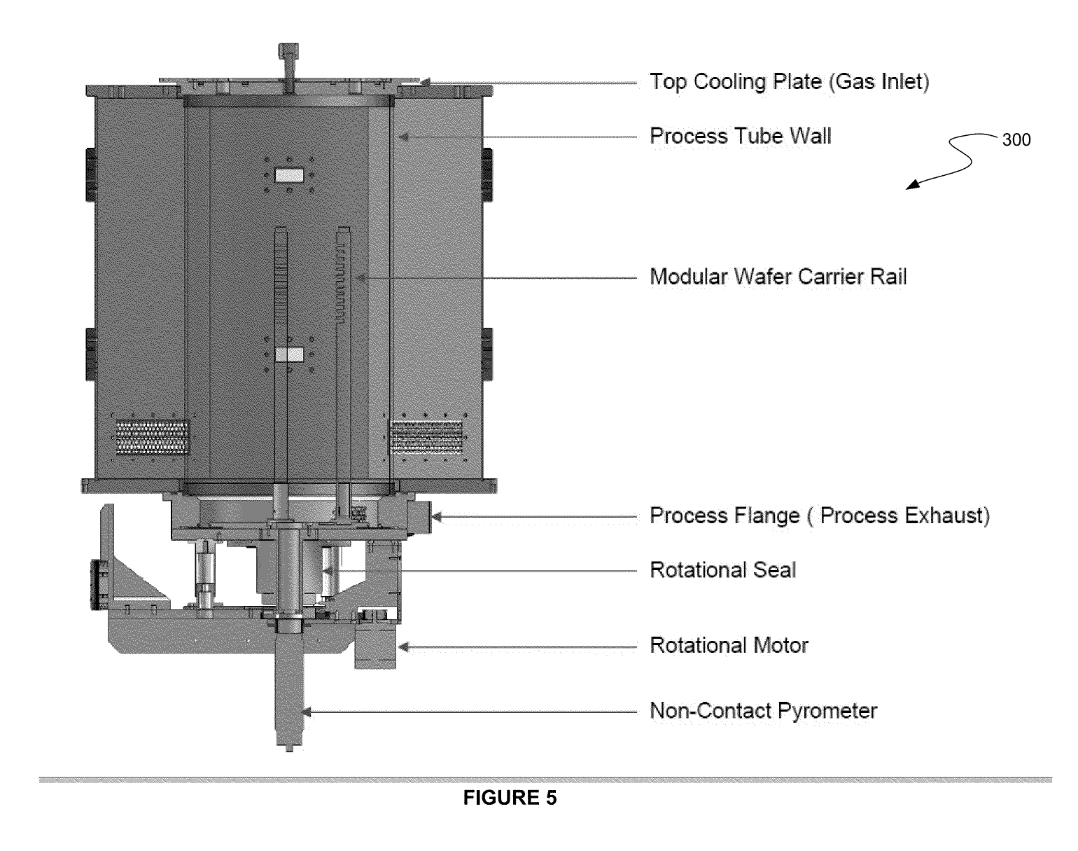

Using a low temperature MW recrystallization, annealing, or activation process to form the doped or undoped epitaxial layer(s) 110 allows the use of a batch reactor. This batch reactor can obtain the needed uniformity and resistivity control while processing more than one wafer at a time. One example of a batch reactor that can be used is depicted in FIG. 4. The batch reactor 200 contains a reactor chamber 205 that is formed by the reactor walls 210. The batch reactor 200 contains an inlet 215 and an outlet 220 for the gas mixture that will be used during the deposition process. The Si-containing gas(es), the carrier gas(es), and/or the dopant gas(es) can be introduced into the inlet 215 either as a single combination of gases or they can be introduced individually. The gas(es) exit via outlet 220 once the MW process is complete.

The reactor 200 also contains quartz susceptor plates 225. The plates 225 can be used with any number of wafers that is limited by the size of the reactor and the size of the area where the MW field is uniform. In some configurations, the number of wafers contained between the susceptor plates 225 can range from 1 to 12. In other configurations, the number of wafers contained between susceptor plates 225 can be one and multiple susceptor plates are used with one wafer between each set.

In some configurations, the quartz susceptor plates on either side of the wafer 225 can act as a microwave reflector and/or a highly doped Si-containing wafer can act as a microwave adsorber. These configurations allow the reactor 200 to focus the MW field into the susceptor plate and through the wafer above it. In other configurations, curved susceptor plates of convex or concave configurations (or combinations thereof) could be used to help make the microwave field uniform across the wafer independent of the applied microwave power.

In some configurations, composite susceptor plates could be used in the reactor 200. In these configurations, the susceptor plates contain adsorbing and reflecting layers in combination that could also be used in additional to the concave and or convex susceptor plates geometries to focus the microwave field at the wafer independent of the applied MW power. Examples of some composite susceptor plate structure include stacks of SOI (silicon-on-insulator) buried layers in Si which can be implanted at various depths with oxygen to generate the desired SiO₂ stacks within the Si wafer.

The reactor 200 also contains at least one MW source 230 that supplies the needed MW energy. In some configurations, the reactor can contain 4 to 20 MW sources. In the configurations illustrated in FIG. 4, the number of MW sources is four. The MW source(s) can be located around the reactor to provide MW energy to the desired locations in the chamber 205, as shown in FIG. 4.

The reactor 200 can contain other components that are used in the deposition reactors in the semiconductor industry. For example, the reactor 200 can contain pyrometers 240 for measuring the temperature in the reaction chamber 205. As well, the reactor can contain pressure sensors, gas flow metering valves, hazardous gas monitors and the like. In other configurations, the batch reactor used for the MW processing using low temperatures could be a combination or hybrid of the batch reactor 200 shown in FIG. 4 and the batch reactor shown in FIG. 5.

The batch reactor 200 can be made of any material that is transparent to microwaves and yet can hold a vacuum. For example, as illustrated in FIG. 4, the reactor walls 210 can comprise quartz. When such a function is not needed, such as in the outer parts of the inlet 215 and the outlet 220, the material of the reactor 200 can be made from other materials, such as steel. In those embodiments where the reactor chamber 205 comprises quartz, it does not adsorb MW and so it will be colder (i.e., about 50° C.) than the wafer temperature, making the batch reactor 200 cheaper to make and safer to operate.

In other embodiments, and under the right conditions, the substrate 105 can be made from a carbon-containing material. Examples of the carbon containing materials in include diamond, graphite, or grapheme. An amorphous (a-C) or polycrystalline carbon layer can then be deposited on that substrate using any process, including when carbon-containing volatile precursors are used in the gas mixture. The polycrystalline or a-C layer can then be converted to an epitaxial carbon layer with a crystalline structure matching the carbon substrate using the low temperature MW processes described herein. As well, the a-C layer and/or the epitaxial carbon layer can be doped and then the dopants activated using the low temperature MW processes described herein.

Using MW processing at low temperatures as described herein provides several features to the resulting semiconductor devices. First, power UMOS devices stacked on power UMOS devices with the upper UMOS device build on an epitaxial layer can be formed in the MW batch reactor at low temperatures. The upper UMOS device could be connected as needed to the lower device with thru-hole vias using amorphous doped Si (that can then be re-crystallized) formed in a grown or deposited oxide layer separating the devices. Second, semiconductor devices such as a UMOS device (with the source on the top and the drain on the bottom) could then have another UMOS device (with the drain on the top and the source on bottom) mounted on top of it with the MW grown epitaxial layer separated by oxide layers as needed. And third, MW processing at low temperatures could be used to attach power devices to other semiconductor devices (such as CMOS or LDMOS devices) in a vertical or horizontal configuration with oxide layers and via holes in between them. These devices can be manufactured since the low temperatures used to form the doped epitaxial or single-crystal Si layers between the insulating layers do not adversely affect the previously formed devices, unlike excessive heat that is used in some conventional epitaxial reactors.

It is understood that all material types provided herein are for illustrative purposes only. Accordingly, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

This application also relates to a batch reactor that comprises: a reaction chamber enclosed by walls made of a material transparent to microwaves; a platen configured to support multiple semiconductor wafers, the platen comprising curved susceptor plates; an inlet for a gas mixture containing a gas mixture capable of forming an epitaxial layer on the wafer; an outlet; and at least one microwave source configured to impinge microwave energy at the wafers, the microwave source configured to emit microwaves at 2.45 GHz to about 5.8 GHz and have a wavelength ranging from about 52 mm to about 123 mm.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method for making an epitaxial layer, comprising:
providing a semiconductor substrate containing an upper surface with a single-crystal structure;
forming a layer on the upper surface of the substrate, wherein the layer comprises substantially the same material as the semiconductor substrate and comprises an amorphous or polycrystalline structure; and
heating the layer using low temperature microwaves to change the amorphous or polycrystalline structure to a single-crystal structure.

2. The method of claim 1, wherein the material comprises Si.

3. The method of claim 1, wherein the material comprises C.

4. The method of claim 1, wherein the low temperature of the heating process is less than about 550° C.

5. The method of claim 1, wherein the low temperature of the heating process ranges from about 200° C. to about 550° C.

6. The method of claim 1, wherein the low temperature of the heating process ranges from about 400° C. to about 550° C.

7. The method of claim 1, further comprising doping the layer with a dopant and then activating the dopant using low temperature microwaves.

8. The method of claim 7, wherein heating by microwaves and the activation by microwaves are performed at substantially the same time.

9. The method of claim 1, wherein the method is performed using a batch reactor which deposits the layer on more than one wafer at substantially the same time.

10. The method of claim 9, wherein the method is performed using a batch reactor which deposits the layer on 1 to 12 wafers at substantially the same time.

11. A method for making an epitaxial layer, comprising:
providing a semiconductor substrate with an upper surface comprising a single-crystal structure; and
forming an epitaxial layer with a single crystal structure on the substrate upper surface using microwaves at a temperature less than about 550° C.

12. The method of claim 11, wherein the material comprises Si.

13. The method of claim 11, wherein the material comprises C.

14. The method of claim 11, wherein the low temperature of the heating process ranges from about 200° C. to about 550° C.

15. The method of claim 11, wherein the low temperature of the heating process ranges from about 400° C. to about 550° C.

16. The method of claim 11, further comprising doping the layer with a dopant and then activating the dopant using low temperature microwaves.

17. The method of claim 16, wherein heating by microwaves and the activation by microwaves are performed at substantially the same time.

18. The method of claim 11, wherein the method is performed using a batch reactor which deposits the layer on more than one wafer at substantially the same time.

19. The method of claim 18, wherein the method is performed using a batch reactor which deposits the layer on 1 to 12 wafers at substantially the same time.

20. A method for making an epitaxial layer, comprising:
providing a semiconductor substrate containing an upper surface with a single-crystal structure;
forming a layer on the upper surface of the substrate using rapid thermal processing, wherein the layer comprises substantially the same material as the semiconductor substrate and comprises an amorphous or polycrystalline structure; and
annealing the layer using microwaves using microwaves at a temperature less than about 550° C. to change the amorphous or polycrystalline structure to a single-crystal structure.
